(19) United States
(12) Patent Application Publication
(10) Pub. No.: US 2004/0137370 A1
(43) Pub. Date: Jul. 15, 2004

(54) Method and apparatus for processing of radiation-sensitive patterning compositions

(76) Inventors: Jeffrey J. Collins, Greeley, CO (US); Thomas R. Jordan, Windsor, CO (US); Ting Tao, Fort Collins, CO (US); Eugene Poland, Ault, CO (US)

Correspondence Address: FAEGRE & BENSON LLP, 2200 Wells Fargo Center, 90 South Seventh Street, Minneapolis, MN, 55402-3901, US

(21) Appl. No.: 10/339,638

(22) Filed: Jan. 9, 2003

(51) Int. Cl. G03F 7/021

(52) U.S. Cl. 430/302; 430/157; 430/394

(57) ABSTRACT

A method and system for processing patterning compositions such as those applied to printing plates are disclosed. An Infrared (IR) oven, instead of a conventional convection oven, is used for preheating image-wise exposed patterning composition before the exposed image is developed. In one embodiment of the invention, a substrate is coated with a layer of a patterning composition. The layer is then image-wise exposed. The coated substrate is then passed under one or more IR emitter tubes to preheat the image-wise exposed patterning composition, which is subsequently developed. The use of an IR oven offers the advantages of more precise and rapid temperature control, smaller system footprint, lower energy consumption and higher throughput as compared to the conventional methods and systems.

### FIELD OF THE INVENTION

The invention relates generally to processing of patterning compositions. More particularly, the invention relates to a method and system for processing such compositions using infrared (IR) as a preheating step.

### BACKGROUND OF THE INVENTION

Photolithography is widely employed in many manufacturing processes, including making printing plates. In a typical process of making a printing plate, a substrate is first coated with a layer of radiation sensitive patterning composition. The layer is then image-wise exposed to radiation. The image-wise exposed layer is treated with a developer, which in the case of a negatively working plate dissolves the unexposed areas in the layer, thereby removing those areas from the substrate and rendering the pattern in the layer.

The patterning compositions for negatively working plates typically includes (a) an acid generator, (b) a cross linking resin or compound, (c) a binder resin (d) an IR absorber, (e) optionally a UV/visible radiation activated acid generator for UV/visible sensitization, and (e) optionally a colorant material such as an ethyl violet, victoria blue or leuco dye. The composition allows for the image-wise exposure, by either IR or UV/visible radiation, of negatively working printing plate precursors, which include supports, or backings, coated with unexposed patterning compositions.

To enhance the quality of the developed image in the layer, it is common to subject the image-wise exposed layer of patterning composition to an overall heating step before developing the image. This is typically referenced as a “preheat step.” The most common method of “preheating” is to move the plates through large ovens, thereby achieving heating by thermal conduction or convection. However, there are several drawbacks to this preheating method.

First, the conventional method of preheating requires a large amount of floor space for the oven. A typical conventional oven may have dimensions of about 190 cm×200 cm×130 cm with an opening of about 130 cm×4.4 cm. Second, the conventional method results in high power consumption at least partially because it is necessary to use large ovens to achieve uniform heating. Third, it is difficult to achieve precise and quick temperature control with the traditional method because temperatures of the larger convection ovens used for preheating can only be controlled via air temperature and air speed. Fourth, the large size of the traditional preheat oven results in a long total time for plate processing.

The invention disclosed herein is aimed at providing a method and system for processing radiation-sensitive patterning compositions substantially without the drawbacks of the conventional approaches.

### SUMMARY OF THE INVENTION

Generally, the invention provides a system and method for processing patterning compositions such as those applied to printing plates wherein an IR oven is used for preheating instead of the conventional convection oven. The use of an IR oven offers the advantages of more precise and rapid temperature control, smaller system footprint, lower energy consumption and higher throughput as compared to the conventional methods and systems. The method and system according to the invention provides end products of the same or better quality than those produced by conventional methods and systems.

### BRIEF DESCRIPTION OF THE DRAWINGS

Other objects and advantages of the invention will become apparent upon reading the following detailed description and upon reference to the drawings in which:

FIG. 1 outlines the steps in a method of processing a printing plate according to an aspect of the invention;

FIG. 2 schematically shows the configuration of an IR oven used to preheat printing plates according to an aspect of the invention;

FIG. 3 schematically shows the configuration of a portion of a system used to process printing plates according to an aspect of the invention, wherein the temperature of a plate being preheated is manually maintained;

FIG. 4 schematically shows the preheating circuit used in the system shown in FIG. 3.

FIG. 5 schematically shows the configuration of a portion of a system used to process printing plates according to an aspect of the invention, wherein the temperature of a plate being preheated is automatically maintained; and

FIG. 6 schematically shows the preheating circuit used in the system shown in FIG. 5.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

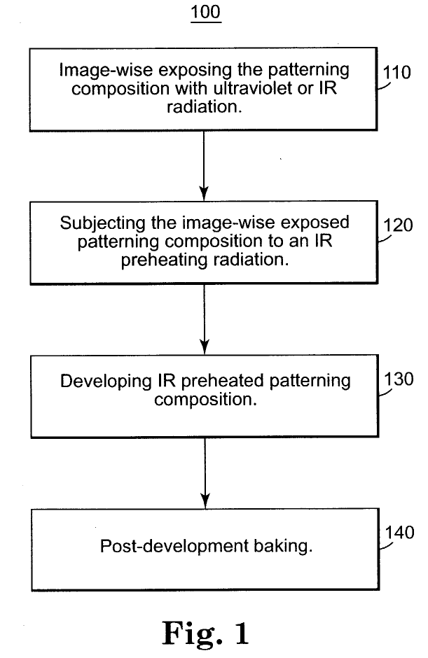

Referring to FIG. 1, a method 100 for processing a radiation-sensitive patterning composition includes image-wise exposing the patterning composition with ultraviolet or IR radiation (110). The patterning composition can be any suitable radiation-sensitive composition, including a layer of photo- or thermally-imagable, negatively-working patterning composition coated on a suitable substrate, such as a printing plate blank. Typically, the substrate has at least one hydrophilic surface. It comprises a support, which may be any material conventionally used to prepare imageable elements useful as lithographic printing plates. The support is preferably strong, stable and flexible. It typically resists dimensional change under conditions of use so that color records will register in a full-color image. It can be any self-supporting material, including, for example, polymeric films such as polyethylene terephthalate film, ceramics, metals, stiff paper, or a lamination of any of these materials. Examples of metal supports include aluminum, zinc, titanium, and alloys thereof. Typically, polymeric films contain a sub-coating on one or both surfaces to modify the surface characteristics to enhance the hydrophilicity of the surface, to improve adhesion to subsequent layers, to improve planarity of paper substrates, and the like. The nature of this layer or layers depends upon the substrate and the composition of subsequent coated layers. Examples of subbing layer materials include adhesion-promoting materials, such as alkoxysilanes, aminopropyltriethoxysilane, glycidoxypropyltriethoxysilane and epoxy functional polymers, as well as other known suitable subbing materials used on polyester bases in photographic films. The surface of an aluminum support may be treated by techniques known in the art, including physical graining, electrochemical graining, chemical graining, and anodizing. The substrate is typically of sufficient thickness to sustain the wear from printing and be thin, typically from about 100 to about 600 μm, and flexible enough to wrap around a printing form. Typically, the substrate comprises an interlayer between the aluminum support and the top layer. The interlayer can be formed by treatment of the support with, for example, silicate, dextrine, hexafluorosilicic acid, phosphate/fluoride, polyvinyl phosphonic acid (PVPA) or polyvinyl phosphonic acid copolymers. The back side of the substrate (i.e., the side opposite the underlayer and top layer) can be coated with an antistatic agent and/or a slipping layer or matte layer to improve handling and “feel” of the imageable element.

“Image-wise exposure”, also referred to as “imaging”, in the context of this application refers to exposure to a radiation with an intensity that varies spatially according to a spatial pattern. Thus, an image-wise exposed layer can have areas that received radiation and those that did not. For example, in half-tone printing, where image-wise radiation can be supplied from a laser imager as a scanning laser beam or an array of laser beams, the filled portions of half-tone cells can be the areas receiving the laser beam or beams, and the unfilled portions can be the unexposed areas.

One way to carryout image-wise exposure is thermal imaging. Thermal imaging of a thermally imageable element may be carried out by well-known methods. The element may be thermally imaged with a laser or an array of lasers emitting modulated near infrared or infrared radiation in a wavelength region that is absorbed by the imageable element. Infrared radiation, especially infrared radiation in the range of about 800 nm to about 1200 nm, typically at 830 nm or 1064 nm, is typically used for imaging thermally imageable elements. Imaging is conveniently carried out with a laser emitting at about 830 nm or at about 1064 nm. Suitable commercially available imaging devices include image setters such as the Creo Trendsetter (CREO) and the Gerber Crescent 42T (Gerber).

The image-wise exposure can also be performed using ultraviolet radiation. Ultraviolet sources are known in the art and include, for example, carbon arc lamps, mercury lamps, xenon lamps, tungsten lamps, and metal halide lamps. Imaging with these light sources is typically carried out by exposure through a photomask. Direct digital imaging, which obviates the need for exposure through a photomask, may be carried out with ultraviolet lasers.

In the next step 120, the image-wise exposed patterning composition is subjected to an IR radiation of a sufficient dosage to ensure that during the pattern development stage 130 (see below), the patterning composition in the areas that received radiation during the image-wise exposure is not removed. This step is believed to serve to use heat generated by the IR radiation to selectively crosslink and solidify the regions of the coating that were selectively imaged and render them preferentially less soluble in a developer. In this sense, this IR radiation step can be viewed as a “preheating” step.

There exists a range of useful amount of IR radiation-generated heat that the plate can be subjected to. Too much heat results in poor release of non-imaged patterning composition from the substrate during the aqueous alkaline development and too little leads to an incomplete and/or soft image. The range of IR heat is dependent on the amount of imaging radiation, amount of time the plate is subjected to IR heat and the type of developer used in development. The IR heat range can then be determined by monitoring the image integrity and non-image areas (see examples below) at various levels of IR heat exposure.

The IR radiation in this step 120 can be applied to the entire coating, for example, by an IR flood lamp. The IR radiation can also be applied only to those areas that received radiation during the image-wise exposure 110. Such location-specific “preheating” radiation 120 can be accomplished, for example, by configuring the same imager that carries out the image-wise radiation to provide an image-wise IR “preheating” exposure.

The image-wise exposed and IR preheated patterning composition is then developed to render the image, or the spatial pattern, in the layer according to well-known processes (130). Any suitable developer, including an aqueous alkaline developer, can be used.

Following development, the printing plate is typically rinsed with water and dried. Drying may be conveniently carried out by infrared radiators or with hot air. After drying, the printing plate can be treated with a gumming solution. A typical gumming solution comprises one or more water-soluble polymers, for example cellulose, polyvinylalcohol, polymethacrylic acid, polymethacrylamide, polyvinylmethylether, polyhydroxyethylmethacrylate, gelatin, and polysaccharide such as dextran, pullulan, gum arabic, and alginic acid. A example material is gum arabic. A developed and gummed plate may also be baked (140), using a conventional oven or an infrared oven similar to the preheating oven described below for preheating, to increase the run length of the plate. Baking can be carried out, for example, at about 220° C. to about 240° C. for about 7 minutes to 10 minutes, or at a temperature of 120° C. for 30 minutes.

The steps above are carried out sequentially in the order described above in most of the illustrative embodiments but need not be. For example, the “preheating” step can be carried out substantially simultaneously with image-wise exposure.

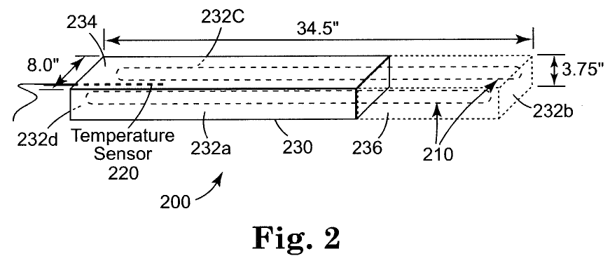

Turning to FIG. 2, which schematically shows the main components of an IR oven 200 as part of one embodiment of the invention. The oven consists of two elongated, round carbon tube emitters 210 (Heraeus Infralight Type No. 45131738LW, Heraeus Noblelight Inc. Atlanta, Ga.) and a temperature sensor 220 positioned between the emitters (or IR lamps). A box 230 made up of 6 mm aluminum covers the IR lamps and temperature sensor on four lateral sides 232a, 232b, 232c and 232d and at the top 234, leaving the bottom 236 open.

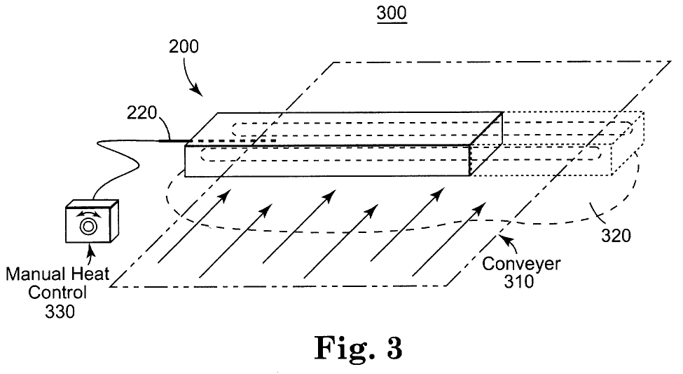

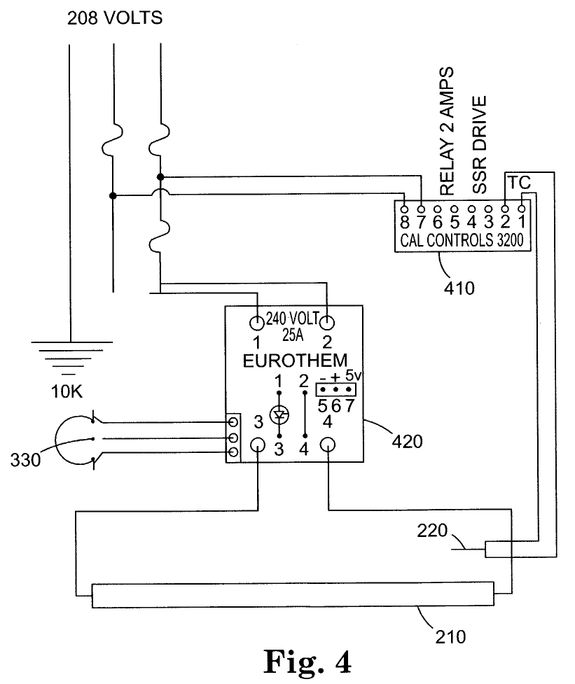

Referring to FIG. 3, the IR oven 200 can be used in a image processing system 300. The IR oven 200 is suspended over a wire-link conveyor 310, which can transport an image-wise exposed printing plate (not shown) through a region 320 below the IR oven 200 to be exposed to the “preheating” IR radiation. The conveyer 310 can be moved at a speed selected within a useful range such that the images-wise exposed printing plate receives the range of useful amount of IR radiation that the plate can be subjected to, as described above. The conveyer 310 in the illustrative embodiments is configured to transport the printing plate in a direction generally transverse to the length direction of the infrared emitters, but can also be otherwise configured to achieve adequate infrared exposure. The conveyor 310 in an illustrative embodiment of the invention is a part of a Wisconsin “Mini” oven (Wisconsin Oven Corp., East Troy, Wis.). The heat radiated by the oven is set manually using a dial 330 and monitored via the temperature sensor 220, which is connected to a digital display (part of the temperature controller 410 (FIG. 4), which in this example is used only as a temperature display. The controller 410 in this embodiment is a Cal Controls 3200, available from Cal Controls, Inc., Libertyville, Ill.) A wiring scheme is depicted in FIG. 4. The dial 330 is connected to a heater power supply 420, for example one of many models made by Eurotherm (Leesburg, Va.), and sets the output power of the power supply 420. The power supply 420 is connected to the IR emitters 210 and supplies electrical power to them.

The speed of the wire-link conveyor 310 in an illustrative embodiment of the invention can be set using the Wisconsin “Mini” Ovens controls. The distance of the bottom 236 of the IR oven 200 box from the conveyor 310 can be any distance that allows the patterning composition to receive adequate amount of IR radiation. In the illustrative embodiment of the invention this distance was about 2.5 cm, or an approximate distance of §4.4 cm from the IR emitter 210 to the lithographic printing plates.

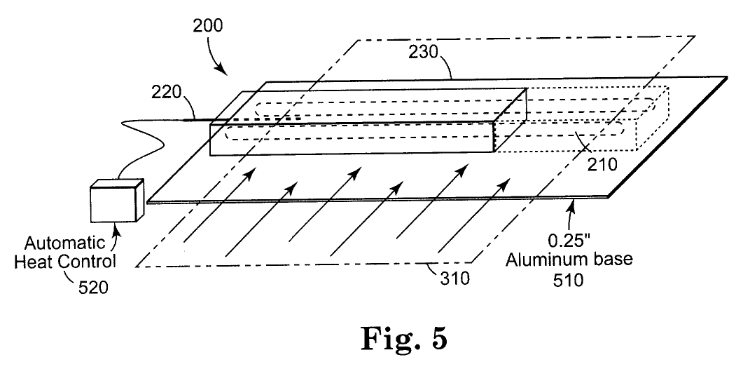

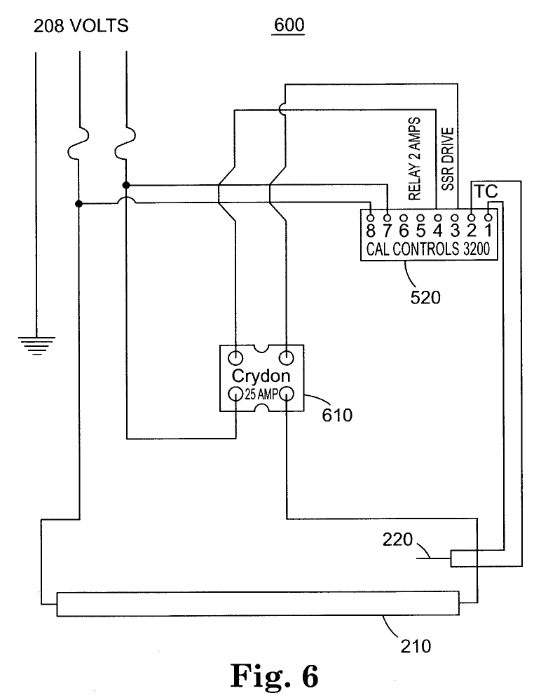

Another illustrative embodiment of the invention, shown in FIGS. 5 and 6, is similar to the embodiment shown in FIGS. 3 and 4 and described above, with the following main differences. A base shield 510, which in this illustrative embodiment is a 6 mm aluminum plate has been secured directly under the IR emitter 210 in such a manner as to allow the wire-link conveyor 310 to pass over the base shield 510, i.e., between the emitters 210 and the base shield 510. A close-loop heat control system 600 in this illustrative embodiment includes a solid state relay 610 (for example one available from Crydom Corp., San Diego, Calif.), which supplies power to the IR emitters 210 and is controlled by a temperature controller 520 (for example Cal Controls 3200). The control system 600 allows for a target temperature to be entered and then automatically maintained. During operation oven 200 is lowered closer to the conveyor to promote heat level stability. The bottom of the oven box 230 in an illustrative embodiment of the invention is set at about 2.9 cm from the secured aluminum base shield 510 and about 1.9 cm from the wire-link conveyor 310, resulting in an approximate distance of 3.8 cm between the IR lamps 210 and lithographic plates.

### EXAMPLES

For examples 1-6 below, an IR oven system as shown in FIGS. 3 and 4 was used; for examples 7-11 below, an IR oven system as shown in FIGS. 5 and 6 was used.

### Example 1

A coating solution was prepared by dissolving the following ingredients into 80 g of 1-methoxy-2-propanol and 3 g of acetone:

6.8 g of 25% resole (Georgia-Pacific, Atlanta, Ga.),

8.4 g of 34% N-13 novolak (Eastman Kodak Company, Rochester, N.Y.),

0.75 g of 2-methoxy-4-(phenylamino)-benzenediazonium hexadecyl sulfate (MSHDS),

0.47 g of Trump IR dye (Eastman Kodak Company, Rochester, N.Y.),

0.02 g of D11 colorant dye (PCAS, Longjumeau, France),

0.05 g of 10% Byk-333 (Byk-Chemie, Wallingford, Conn.), and

0.2 g of 10% Byk-307 (Byk-Chemie, Wallinfort, Conn.).

MSHDS is an acid-generating agent and was prepared according to the U.S. patent application Ser. No. 10/155,696, entitled “Selected Acid Generating Agents and Their Use In Processes for Imaging Radiation-Sensitive Elements”, filed May 24, 2002 and assigned to the same assignee as the present application. The application Ser. No. 10/155,696 also discloses a number of other suitable acid-generating agents, including 2-methoxy-4-(phenylamino)-benzenediazonium dodecyl sulfate (MSDS) and 2-methoxy-4-(phenylamino)-benzenediazonium octyl sulfate (MSOS). The U.S. patent application Ser. No. 10/155,696 is incorporated herein by reference.

An electrochemically grained and anodized aluminum substrate, post-treated with polyvinylphosphoric acid (PVPA), was coated with the above solution. The dry coating weight was approximately 1.4 g/m². When properly dried at 88° C. for about 2 minutes on a rotating drum a thermal printing plate was obtained. This printing plate was used in the processing method presented above. Plate material, with dimensions of about 13 cm×38 cm×0.3 mm, were preheated using the IR oven at a throughput speeds of 0.76, 0.91, 1.0 and 1.2 m/min, respectively, at a temperature of 179±2° C. The plates were then processed at a throughput speed of 0.76 m/min in a Quartz 850 processor (Kodak Polychrome Graphics) charged with Protherm Concentrate developer (Kodak Polychrome Graphics) at 25° C. to determine the minimum amount of heat (fog point) required to render the plate non-processable. The results are shown in Table I.

TABLE I

| IR Oven Through-Put Speed | Result |
|---|---|
| 0.76 m/min | Non-processable (fog) |
| 0.91 m/min | Non-processable (fog) |
| 1.0 m/min | Clear-out of background |
| | (clean) |
| 1.2 m/min | Clear-out of background |
| | (clean) |

### Example 2

A printing plate described in Example 1 was exposed by an Olec Ultraviolet light frame utilizing an Olix integrator (Olec Corporation of Irvine, Calif.) and processed using the method presented above. A calibration curve was developed for the purpose of estimating the ultraviolet (UV) energy in these examples. That curve was based on the equation y=12.68x−11.972, with an R² of 0.9976, where y is the UV energy in mJ/cm² and x is the length of exposure in seconds. Plate material, with dimensions of 19 cm×69 cm×0.3 mm, was exposed with ˜750 mJ/cm² of UV energy through a negative film. The material was then preheated using the same IR oven as used in Example 1 at a temperature of 179° C. and throughput speed of n1.2 m/min. The plates were processed at a throughput speed of 0.76 m/min in a Quartz 850 processor (Kodak Polychrome Graphics, Norwalk, Conn.) charged with Protherm Concentrate (Kodak Polychrome Graphics) developer at 25° C. The result, through visual inspection, was an acceptable image deemed no different than an image observed on similar plate material after preheating with a conventional Wisconsin Heavy Duty Oven (Wisconsin Oven Corporation of East Troy, Wis.).

### Example 3

A Thermal Gold printing plate (Kodak Polychrome Graphics) was exposed by an Olec Ultraviolet light frame utilizing an Olix integrator (Olec Corporation of Irvine, Calif.) and processed using the method presented above. A calibration curve was developed for the purpose of estimating the ultraviolet (UV) energy in these examples. That curve was based on the equation y=12.68x−11.972, with an R² of 0.9976, where y is the UV energy in mJ/cm² and x is the length of exposure in seconds. Plate material, with dimensions of 19 cm×69 cm×0.3 mm, was exposed with ˜750 mJ/cm² of UV energy through a negative film. The material was then preheated using IR emitter tubes (Heraeus InfraLight Type No. 45131738) at a temperature of 179° C. and throughput speed of 1.2 m/min. The plates were processed at a throughput speed of 0.76 m/min in a Quartz 850 processor (Kodak Polychrome Graphics) charged with Protherm Concentrate (Kodak Polychrome Graphics) developer at 25° C. The results were compared by visual inspection with similar plate material and image preheated at 127° C. with a conventional Wisconsin Heavy Duty Oven (Wisconsin Oven Corporation of East Troy, Wis.) and processed in the same processor described above at a through—put of 0.76 m/min. The image was deemed no different than the image observed on the similar plate material preheated with the conventional oven.

### Example 4

A printing plate described in Example 1 was exposed by a Creo 3244 Trendsetter digital platesetter (CreoScitex Corporation of Vancouver, BC Canada), which employs an infrared imaging source operating at 830 nm, and processed using the method presented above. Plate material, with dimensions of 38 cm×69 cm×0.3 mm, was exposed via the digital platesetter at the experimental plates optimum power of 80 mJ/cm² and 250 rpm. The material was then preheated using IR emitter tubes (Heraeus InfraLight Type No. 45131738) at a temperature of 179° C. and throughput speed of 1.2 m/min. The plates were processed at a through-put speed of 0.76 m/min in a Quartz 850 processor (Kodak Polychrome Graphics) charged with Protherm Concentrate (Kodak Polychrome Graphics) developer at 25° C. The results were compared by visual inspection with similar plate material and image preheated at 127° C. with a conventional Wisconsin Heavy Duty Oven (Wisconsin Oven Corporation) and processed in the same processor described above at a throughput of 0.76 m/min. The image was deemed no different than the image observed on the similar plate material preheated with the conventional oven.

### Example 5

A Thermal Gold printing plate (Kodak Polychrome Graphics) was exposed by a Creo 3244 Trendsetter digital platesetter (CreoScitex Corporation) and processed using the method presented above. Plate material, with dimensions of 38 cm×69 cm×0.3 mm, was exposed via the digital platesetter at Thermal Gold's optimum power of 100 mJ/cm² and 250 rpm. The material was then preheated using IR emitter tubes (Heraeus InfraLight Type No. 45131738) at a temperature of 179° C. and throughput speed of 1.2 m/min. The plates were processed at a through-put speed of 0.76 m/min in a Quartz 850 processor (Kodak Polychrome Graphics) charged with Protherm Concentrate (Kodak Polychrome Graphics) developer at 25° C. The results were compared by visual inspection with similar plate material and image preheated at 127° C. with a conventional Wisconsin Heavy Duty Oven (Wisconsin Oven Corporation) and processed in the same processor described above at a throughput of 0.76 m/min. The image was deemed no different than the image observed on the similar plate material preheated with the conventional oven.

### Example 6

A Thermal Newspaper printing plate (Kodak Polychrome Graphics) was exposed by a Creo 3244 Trendsetter digital platesetter (CreoScitex Corporation) and processed using the method presented above. Plate material, with dimensions of 38 cm×69 cm×0.3 mm, was exposed via the digital platesetter at Thermal Newspaper's optimum power of 130 mJ/cm² and 250 rpm. The material was then preheated using !R emitter tubes (Heraeus InfraLight Type No. 45131738) at a temperature of 179° C. and throughput speed of 1.2 m/min. The plates were processed at a through-put speed of 0.82 m/min in a PHW32 processor (Kodak Polychrome Graphics) charged with 980 negative plate developer (Kodak Polychrome Graphics) developer at 25° C. The results were compared by visual inspection with similar plate material and image preheated at 127° C. with a conventional Wisconsin Heavy Duty Oven (Wisconsin Oven Corporation) and processed in the same processor described above at a throughput of 0.76 m/min. The image was deemed no different than the image observed on the similar plate material preheated with the conventional oven.

### Example 7

A printing plate described in Example 1 was used in the processing method presented above. Plate material, with dimensions of 13 cm×38 cm×0.3 mm, were preheated at various temperatures using the IR oven at a throughput speed of 1.1 m/min. The plates were processed at a matching through-put speed of 1.1/min in a Quartz 850 processor (Kodak Polychrome Graphics) charged with Protherm Concentrate developer (Kodak Polychrome Graphics) at 25° C. to determine the minimum amount of heat (fog point) required to render the plate non-processable. The results are shown in Table II.

TABLE II

| IR Oven Temperatures | Result |
|---|---|
| 216°, 199° and 193° C. | Non-processable (fog) |
| 192° C. | Non-processable (light fog, |
| | i.e. fog point) |
| 188° C. | Clear-out of background |
| | (clean) |

### Example 8

A Thermal Gold printing plate (Kodak Polychrome Graphics) was used in the processing method presented above. Plate material, with dimensions of 13 cm×38 cm×0.3 mm, were preheated at various temperatures using the IR oven at a throughput speed of 1.1 μm/min. The plates were processed at a matching through-put speed of 1.1 m/min in a Quartz 850 processor (Kodak Polychrome Graphics) charged with Protherm Concentrate developer (Kodak Polychrome Graphics) at 25° C. to determine the minimum amount of heat (fog point) required to render the plate non-processable. The results are shown in Table III.

TABLE III

| IR Oven Temperatures | Result |
|---|---|
| 199° and 193° C. | Non-processable (fog) |
| 188° C. | Non-processable (light fog, |
| | i.e. fog point) |
| 182° C. | Clear-out of background |
| | (clean) |

### Example 9

The printing plate described in Example 1 was exposed by an Olec Ultraviolet light frame utilizing an Olix integrator (Olec Corporation) and processed using the method presented above. A calibration curve was developed for the purpose of estimating the ultraviolet (UV) energy in these examples. That curve was based on the equation y=12.68x−11.972, with a R² of 0.9976, where y is the UV energy in mJ/cm² and x is the length of exposure in seconds. Plate material, with dimensions of 19 cm×69 cm×0.3 mm, was exposed to UV energy through a negative film at times of 30, 15, 10, and 5 seconds. The material was set on the conveyor lengthwise, resulting in a definite head (first part of plate encountering heat) and tail. The material was then preheated at 182° C. using the IR oven at a throughput speed of 1.1 m/min. The plates were processed at a matching through-put speed of 1.1 μm/min in a Quartz 850 processor (Kodak Polychrome Graphics) charged with Protherm Concentrate developer (Kodak Polychrome Graphics) at 25° C. The results were compared by visual inspection with the same plate material and image preheated at 127° C. with a conventional Wisconsin Heavy Duty Oven (Wisconsin Oven Corporation) and processed in the same processor described above at the standard recommended throughput of 0.76 m/min. The goal of the comparison was to determine if the processed image obtained via IR oven preheat was of equal quality to that obtained by conventional preheat. These experiments were then repeated at an IR oven temperature of 177° C. The results are presented in Table IV.

TABLE IV
UV Exposure

| | | |
|---|---|---|
| Time(s) | mJ/cm² | Comparative Results |

IR Oven Temperature of 182° C.

| | | |
|---|---|---|
| 30 | 368 | Good Image Area/Clean Non-Image |
| | | Area |
| 15 | 178 | Good Image Area/Clean Non-Image |
| | | Area |
| 10 | 115 | Good Image Area/Clean Non-Image |
| | | Area |
| 5 | 51 | Strong Image Area at head of plate |
| | | with weak to no image at tail of |
| | | plate/Clean Non-Image Area |

IR Oven Temperature of 177° C.

| | | |
|---|---|---|
| 30 | 368 | Good Image Area/Clean Non-Image |
| | | Area |
| 15 | 178 | Good Image Area/Clean Non-Image |
| | | Area |
| 10 | 115 | Strong Image Area at head of plate |
| | | with weak to no image at tail of |
| | | plate/Clean Non-Image Area |
| 5 | 51 | Strong Image Area at head of plate |
| | | with weak to no image at tail of |
| | | plate/Clean Non-Image Area |

### Example 10

The printing plate described in Example 1 was exposed by a Creo 3244 Trendsetter digital platesetter (CreoScitex Corporation) and processed using the method presented above. Plate material, with dimensions of 19 cm×69 cm×0.3 mm, was exposed via the digital platesetter at the experimental plates optimum power of 80 mJ/cm² and 250 rpm. The imaged plate material was cut to the dimensions 5.4 cm×69 cm. The result was multiple parts of the same plate material containing the same image. The material was set on the conveyor lengthwise, resulting in a definite head (first part of plate encountering heat) and tail and preheated at 182, 177 and 171° C. using the IR oven at a throughput speed of 1.1 m/min. The plates were processed at a matching through-put speed of 1.1 m/min in a Quartz 850 processor (Kodak Polychrome Graphics) charged with Protherm Concentrate developer (Kodak Polychrome Graphics) at 25° C. The results were compared by visual inspection with the same plate material and digital image preheated at 127° C. with a conventional Wisconsin Heavy Duty Oven (Wisconsin Oven Corporation) and processed in the same processor described above at the standard recommended throughput of 0.76 m/min. The goal of the comparison was to determine if the processed image obtained via IR oven preheat was of equal quality to that obtained via conventional preheat. The results are shown in Table V.

TABLE V

| IR Oven Temperature | Comparative Results |
|---|---|
| 182° C. | Good Image Area/Clean Non-Image Area |
| 177° C. | Good Image Area/Clean Non-Image Area |
| 171° C. | Slight image banding (sign of low preheat |
| | temperature) |

### Example 11

The Thermal Gold printing plate (Kodak Polychrome Graphics) was exposed by a Creo 3244 Trendsetter digital platesetter (CreoScitex Corporation) and processed using the method presented above. Plate material, with dimensions of 38 cm×69 cm×0.3 mm, was exposed via the digital platesetter at the experimental plates optimum power of 100 mJ/cm² and 250 rpm. The imaged plate material was cut to the dimensions 5.4 cm×69 cm. The result was multiple parts of the same plate material containing the same image. The material was set on the conveyor lengthwise, resulting in a definite head (first part of plate encountering heat) and tail and preheated at 182, 177 and 171° C. using the IR oven at a throughput speed of 1.1 m/min. The plates were processed at a matching through-put speed of 1.1 m,/min in a Quartz 850 processor (Kodak Polychrome Graphics) charged with Protherm Concentrate developer (Kodak Polychrome Graphics) at 25° C. The results were compared by visual inspection with the same plate material and digital image preheated at 127° C. with a conventional Wisconsin Heavy Duty Oven (Wisconsin Oven Corporation) and processed in the same processor described above at the standard recommended throughput of 0.76 m/min. The goal of the comparison was to determine if the processed image obtained via IR oven preheat was of equal quality to that obtained via conventional preheat. The results are shown in Table VI.

TABLE VI

| IR Oven Temperature | Comparative Results |
|---|---|
| 182° C. | Good Image Area/Clean Non-Image Area |
| 177° C. | Good Image Area/Clean Non-Image Area |
| 171° C. | Slight image banding (sign of low preheat |
| | temperature) |

This invention has addressed several significant issues. First, the space (footprint) taken up by the large conventional preheat ovens is significantly reduced, for example to 20 cm×137 cm×10 cm with an opening of 132 cm×3.8 cm. Temperatures of the larger convection ovens used for preheating can only be controlled via air temperature and air speed. This combined with the need to heat uniformly results in the large size, introduction of significant noise and heat to the immediate surroundings and slow reaction times of these oven types. IR ovens provide an alternative that produces the same temperature consistency with a smaller footprint. Second, IR is an “energy source” that can be switched on and off with rapid response, resulting in a heat source that can be quickly engaged and directly regulated. The more rapid power-up and power-down cycles for the IR ovens provide considerable energy savings. Additionally, the smaller size of the IR ovens and non-reliance on air movement (IR emitters can be used to heat in a vacuum) result in the significant reduction of noise and heat introduced to the immediate surroundings. The controllability of the IR emitter provides an oven that maintains consistent heat in a compact configuration, thus reducing the overall footprint and throughput times of the current processing method.

With an IR emitter oven, the same amount of heat energy is applied to the plate, but the reduced size increases output by decreasing time spent in the processing line. For example a typical processing system, consisting of an oven and processor, is approximately 3.6 m long (with the preheat oven taking up about 2.5 m). Incorporating an IR oven of only 25 cm results in a system of 1.3 m in length. With no change in the processing system speed the amount of time to process a plate is more than halved (˜60%).

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method of forming a pattern in a layer of radiation-sensitive patterning composition, the method comprising:
(a) subjecting the layer of patterning composition to a radiation according to a spatial pattern of areas exposed to the radiation and areas not exposed to the radiation;
(b) subjecting the layer of patterning composition to an infrared radiation;
(c) developing the spatial pattern in the layer of patterning composition, the infrared radiation in step (b) being of a sufficient dosage to prevent the areas exposed to the radiation in step (a) from being completely removed during step (c).

2. The method of claim 1, wherein steps (a), (b) and (c) are carried out sequentially in the order recited therein.

3. The method of claim 1, wherein step (b) comprises energizing an infrared emitter and conveying the layer of patterning composition through a region disposed to receive the infrared radiation from the emitter.

4. The method of claim 1, wherein the infrared radiation in step (b) heats the layer of patterning composition.

5. The method of claim 1, wherein the radiation in step (a) comprises an infrared radiation.

6. The method of claim 1, wherein the radiation in step (a) comprises an ultraviolet radiation.

7. The method of claim 3, wherein the step of conveying comprises conveying the layer of patterning composition at a speed within a predetermined range of speeds.

8. A method of making a printing plate, the method comprising:
(a) coating a substrate with a layer of radiation-sensitive patterning composition;
(b) subjecting the layer of patterning composition to a radiation according to a spatial pattern of areas exposed to the radiation and areas unexposed to the radiation
(c) subjecting the layer of patterning composition to an infrared radiation;
(d) developing the spatial pattern in the layer of patterning composition, wherein step (c) comprises subjecting the layer of patterning composition to an infrared radiation of a sufficient dosage to prevent the patterning composition in the areas exposed to the radiation in step (a) from being completely removed from the substrate during step (d).

9. The method of claim 8, wherein step (a) comprises coating the substrate with a patterning composition containing an acid generation agent selected from the group consisting of 2-methoxy-4-(phenylamino)-benzenediazonium dodecyl sulfate (MSDS); 2-methoxy-4-(phenylamino)-benzenediazonium hexadecyl sulfate (MSHDS); and 2-methoxy-4-(phenylamino)-benzenediazonium octyl sulfate (MSOS).

10. A system for forming a pattern in a layer of radiation-sensitive patterning composition, the system comprising:
(a) a first radiation source adapted to project a first radiation on the layer of patterning composition to a radiation according to a spatial pattern of areas exposed to the radiation and areas not exposed to the radiation;
(b) a second radiation source comprising an infrared emitter and adapted to project an infrared radiation on the layer of patterning composition;
(c) a development module adapted to apply a developer to develop the spatial pattern in the layer of patterning composition.

11. The system of claim 10, further comprising a conveyer adapted to move the layer of patterning composition through a region disposed to receive the infrared radiation from the second radiation source.

12. The system of claim 11, wherein the first radiation source comprises an infrared source.

13. The system of claim 11, wherein the first radiation source comprises an ultraviolet source.

14. The system of claim 10, wherein the first radiation source comprises a laser source.

15. The system of claim 11, wherein the infrared emitter has an elongated shape, and disposed lengthwise along an axis, and the conveyer is adapted to move the layer of patterning composition along a path in a direction generally transverse to the axis.

16. The system of claim 15, further comprising a housing adapted to partially shield the radiation from the infrared emitter, wherein the housing defines an opening through which an overall infrared radiation from the emitter can be projected on the layer of patterning composition.

17. The system of claim 16, further comprising an infrared shield disposed, wherein the path of transporting the patterning composition is generally located between the infrared emitter and the shield.
